(19) United States
(12) Patent Application Publication
(10) Pub. No.: US 2018/0264524 A1
(43) Pub. Date: Sep. 20, 2018

(54) TEMPLATE CLEANING METHOD, TEMPLATE CLEANING APPARATUS, AND CLEANING LIQUID

(71) Applicant: TOSHIBA MEMORY CORPORATION, Tokyo (JP)

(72) Inventors: Yumi TANAKA, Ebina (JP); Kenji Iwade, Hiratsuka (JP); Hirotaka Ogihara, Yokohama (JP)

(73) Assignee: TOSHIBA MEMORY CORPORATION, Tokyo (JP)

(21) Appl. No.: 15/698,512

(22) Filed: Sep. 7, 2017

(30) Foreign Application Priority Data
Mar. 17, 2017 (JP) 2017-053556

(51) Int. Cl. B08B 3/08; B08B 3/10; B08B 7/00; G03F 7/00

(52) U.S. Cl. CPC B08B 3/08; G03F 7/0002; B08B 7/0035; B08B 3/10

(57) ABSTRACT

According to one embodiment, there is provided a template cleaning method. The method includes cleaning a template with a pattern formed on a surface, by using an acid or alkali. The method includes cleaning the template by using a cleaning liquid. The method includes rinsing the template by using a rinse liquid. The method includes performing an ashing process to the surface of the template by using a process gas. The cleaning liquid contains at least an auxiliary agent and a pH adjuster. The auxiliary agent contains grains made of a material that contains an organic substance as a main component.

### CROSS-REFERENCE TO RELATED APPLICATIONS

This application is based upon and claims the benefit of priority from Japanese Patent Application No. 2017-053556, filed on Mar. 17, 2017; the entire contents of which are incorporated herein by reference.

### FIELD

Embodiments described herein relate generally to a template cleaning method, a template cleaning apparatus, and a cleaning liquid.

### BACKGROUND

In a nanoimprint lithography technique, a resist is applied onto a substrate, and a template is pressed against the resist on the substrate to transfer a pattern on the template onto the resist on the substrate. When this pattern transfer is performed, it is desirable that the pattern on the template be free from particles attaching thereto.

### BRIEF DESCRIPTION OF THE DRAWINGS

FIG. 1 is a diagram illustrating the configuration of a template cleaning apparatus according to an embodiment;

FIG. 2 is a diagram illustrating the configuration of a cleaning module in the embodiment;

FIG. 3 is a diagram illustrating the configuration of an ashing module in the embodiment;

FIG. 4 is a flowchart illustrating a template cleaning method according to the embodiment;

FIGS. 5A and 5B are diagrams illustrating the template cleaning method according to the embodiment;

FIGS. 6A and 6B are diagrams illustrating the template cleaning method according to the embodiment;

FIG. 7A is a diagram illustrating the surface potential (seta potential) of an auxiliary agent in the embodiment;

FIG. 7B is a diagram illustrating the surface potential (zeta potential) of a template in the embodiment; and

FIGS. 8A to 8C are diagrams illustrating the template cleaning method according to the embodiment.

### DETAILED DESCRIPTION

In general, according to one embodiment, there is provided a template cleaning method. The method includes cleaning a template with a pattern formed on a surface, by using an acid or alkali. The method includes cleaning the template by using a cleaning liquid. The method includes rinsing the template by using a rinse liquid. The method includes performing an ashing process to the surface of the template by using a process gas. The cleaning liquid contains at least an auxiliary agent and a pH adjuster. The auxiliary agent contains grains made of a material that contains an organic substance as a main component.

Exemplary embodiments of template cleaning method will be explained below in detail with reference to the accompanying drawings. The present invention is not limited to the following embodiments.

### Embodiment

An explanation will be given of a template cleaning apparatus according to an embodiment. There is a case where a nanoimprint lithography technique is used for manufacturing semiconductor devices. In the nanoimprint lithography technique, a template with a pattern formed on its surface is prepared. After a resist is applied onto a substrate, the surface of the template is pressed against the resist on the substrate, so transfer the pattern on the template surface onto the resist on the substrate. Because the resist attaches onto the template surface during the pattern transfer, a cleaning process for removing the resist from the template surface is performed by using a cleaning agent, such as an acid or alkali, after the pattern transfer.

At this time, particles are left attaching on the template surface without being removed, as the case may be. If the pattern transfer is performed to the next substrate while particles are left attaching on the template surface, defective pattern formation may be caused. For example, where line patterns or space patterns are formed as recessed portions on the template surface, particles attaching inside the recessed portions are not removed by cleaning for resist removal, but are likely so be left attaching on the template surface. Where pillar patterns or hole patterns are formed as recessed portions on the template surface, particles attaching inside the recessed portions are not removed by a cleaning process for resist removal, but are likely to be left attaching on the template surface.

In consideration of the above, according to this embodiment, the surface potential of fine grains of an auxiliary agent is set to have a polarity reverse to that of the surface potential of particles. In this state, the particles are caused to attach to the fine grains of the auxiliary agent, and then the fine grains of the auxiliary agent with the particles attaching thereto are removed. Consequently, it is achieved to improve the efficiency of removing the particles.

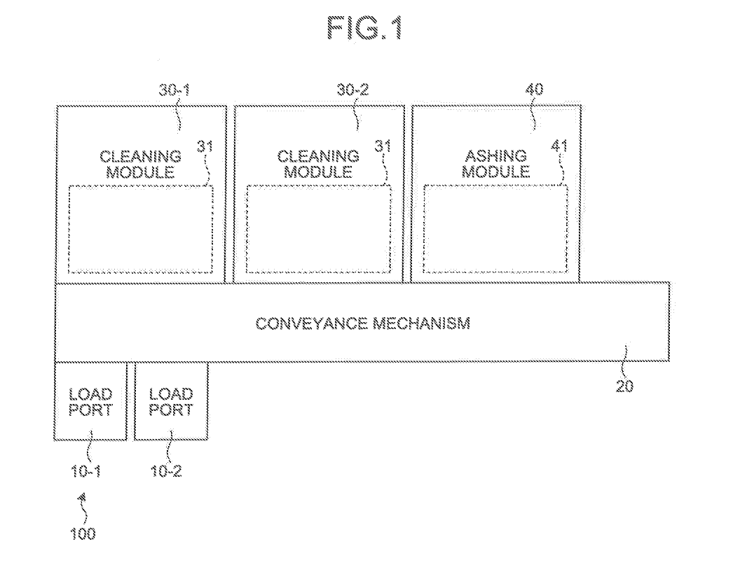

Specifically, cleaning of the template is performed by using a template cleaning apparatus 100 illustrated in FIG. 1. FIG. 1 is a diagram illustrating the configuration of the template cleaning apparatus 100.

The template cleaning apparatus 100 includes a plurality of load ports 10-1 and 10-2, a conveyance mechanism 20, a plurality of cleaning modules 30-1 and 30-2, and an ashing module 40.

The plurality of load ports 10-1 and 10-2 are arranged adjacent to the conveyance mechanism 20. In each load port 10, a template 5 to be processed in the template cleaning apparatus 100 is placed. The plurality of load ports 10-1 and 10-2 are provided to perform cleaning to a plurality of templates 5 in parallel. For example, the template 5 is made of a material that contains silicon oxide as the main component, and may be made of a silicon oxide crystal (quartz).

The conveyance mechanism 20 conveys templates 5 between each load port 10, each cleaning module 30, and the ashing module 40. For example, the conveyance mechanism 20 conveys a template 5 placed on a load port 10 to a cleaning module 30.

The plurality of cleaning modules 30-1 and 30-2 are arranged adjacent to the conveyance mechanism 20. Each cleaning module 30 includes a process chamber 31 used for performing a cleaning process for removing resist and particles attaching to each template 5. The template 5 to be subjected to cleaning is loaded into the process chamber 31 by the conveyance mechanism 20. The cleaning module 30-1 may be a cleaning module for acid cleaning. The cleaning module 30-2 may be a cleaning module for alkali cleaning.

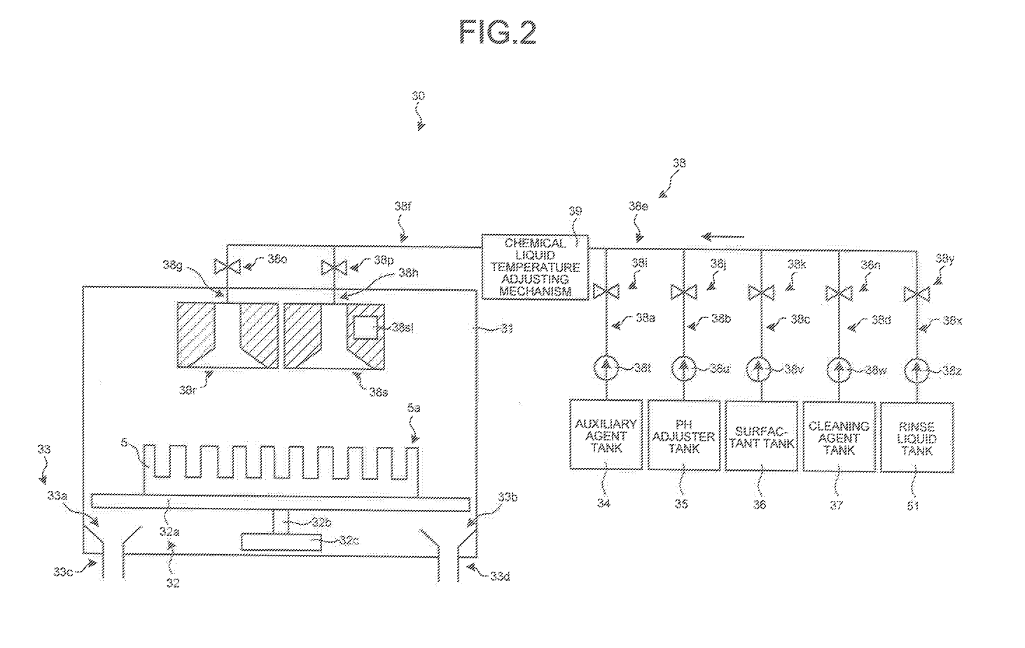

More specifically, each cleaning module 30 has a configuration as illustrated in FIG. 2. FIG. 2 is a diagram illustrating the configuration of the cleaning module 30. The cleaning module 30 includes the process chamber 31, a spin module 32, a waste liquid piping 33, an auxiliary agent tank 34, a pH adjuster tank 35, a surfactant tank 36, a cleaning agent tank 37, a rinse liquid tank 51, a supply piping 38, and a chemical liquid temperature adjusting mechanism 39.

The spin module 32 is arranged in the process chamber 31, and rotatably holds the template 5 loaded in the process chamber 31. The spin module 32 includes a stage 32a, a shaft 32b, and a drive mechanism 32c. The template 5 is placed on the upper surface of the stage 32a, The stage 32a includes a chucking mechanism, such as an electrostatic chuck or vacuum chuck, and holds the placed template 5 by the chucking mechanism. The drive mechanism 32c can rotationally drive the stage 32a through the shaft 32b while the template 5 is held on the stage 32a.

The supply piping 38 includes supply pipes 38a, 38b, 38c, 38d, 38e, 38f, 38g, 38h, and 38x, switching valves 38i, 38j, 38k, 38n, 38o, 38p, and 38y, pumps 38t, 38u, 38v, 38w, and 38z, and delivery ports 38r and 38s. The delivery port 38r is a delivery port for ordinary cleaning. The delivery port 38s is a delivery port for physical cleaning, and includes ultrasonic transducer (vibration imparting mechanism; 38s1. The delivery port 38s supplies ultrasonic waves from the ultrasonic transducer 38s1 to a chemical liquid being delivered, to generate cavities (micro-babbles) In the chemical liquid.

The chemical liquid temperature adjusting mechanism (vibration imparting mechanism) 39 is arranged between the supply pipe 38e and the supply pipe 38f. The chemical liquid temperature adjusting mechanism 39 includes a heater, for example, and can adjust the temperature of the chemical liquid by heating the passing chemical liquid by using the heater.

The auxiliary agent tank 34 stores an auxiliary agent. The auxiliary agent is a chemical liquid for assisting a cleaning process using a cleaning agent to be performed to the template 5. The auxiliary agent contains grains of an organic substance. For example, the organic substance may be made of a resin (resin) containing no metal. The organic substance contains a material that contains as the main component at least one selected from the group consisting of a styrene-based resin, acrylic-based resin, acrylic styrene-based resin, and melanin-based resin. For example, the organic substance contains polystyrene. The average primary grain diameter of the grains contained in the auxiliary agent may be set to correspond to the minimum dimension of the pattern formed on the template surface (for example, several 10 nm to 60 nm), and may be set to 5 nm or larger and 60 nm or smaller, for example.

The surfactant tank 36 stores a surfactant. The surfactant is a chemical liquid for adjusting the surface potential (zeta potential) of particles attaching to the template 5, to liberate the particles from the template 5. For example, the surfactant may be an anionic surfactant, cationic surfactant, nonionic surfactant, or combination thereof. In other words, for example, the surfactant contains a material that contains as the main component at least one selected from the group consisting of an anionic surfactant, cationic surfactant, and nonionic surfactant. The anionic surfactant encompasses dodecylbensene sulfonate salt, polymeric polyacrylate salt, and the like. The cationic surfactant encompasses aliphatic amine salt, aliphatic ammonium salt, and the like. The nonionic surfactant encompasses polyvinyl pyrrolidone (PVP), acetylene glycol, a silicone-based surfactant, polyvinyl alcohol, polyvinylmethyl ether, hydroxyethyl cellulose, and the like.

For example, when the surface potential of the template 5 is a negative potential, the surfactant may contain an anionic surfactant as the main component. On the other hand, when the surface potential of the template is a positive potential, the surfactant may contain a cationic surfactant as the main component. This enables the surface potential of particles to be the same in polarity as the surface potential of the template 5, and thus an electrical repulsive force can come to work between the particles and the template 5.

The pH adjuster tank 35 stores a pH adjuster. The pH adjuster is a chemical liquid for adjusting the surface potential (zeta potential) of the auxiliary agent, to cause particles to attach to the auxiliary agent. The pH adjuster adjusts the surface potential (zeta potential) of the auxiliary agent to a polarity reverse to that of the surface potential of the particles. For example, the pH adjuster contains potassium hydroxide and/or sulfuric acid.

The cleaning agent tank 37 stores a cleaning agent. The cleaning agent is a chemical liquid for removing resist attaching to the template 5.

For example, when the cleaning module 30 is a cleaning module for acid cleaning, the cleaning agent is SPM (a mixed liquid of sulfuric acid with hydrogen peroxide solution), HPM (a mixed liquid of hydrochloric acid with hydrogen peroxide solutions, COM (a mixed liquid of hydrochloric acid with ozone water), or the like. On the other hand, when the cleaning module 30 is a cleaning module for alkali cleaning, the cleaning agent is SCl (a mixed liquid of ammonia with hydrogen peroxide solution), NC2 (a mixed liquid of TMY (trimethyl-2 hydroxyethyl ammonium hydroxide) with hydrogen peroxide solution), or the like.

The rinse liquid tank 51 stores a rinse liquid. The rinse liquid is a liquid for rinsing the template 5. For example, the rinse liquid is pure water or ultrapure water.

The waste liquid piping 33 discharges waste liquid generated by a cleaning process performed to the template 5 (such as the used cleaning agent, auxiliary agent, pH adjuster, surfactant, and the like after the cleaning process) to outside the process chamber 31. The waste liquid piping 33 includes waste liquid ports 33a and 33b and drain pipes 33c and 33d. The waste liquid ports 33a and 33b are arranged near the outer periphery of the stage 32a, and waste liquid guided to the outer periphery of the stage 32a can flow into the waste liquid ports 33a and 33b. The drain pipes 33c and 33d discharge the waste liquid flowing into the waste liquid ports 33a and 33b to outside the process chamber 31.

Returning back to FIG. 1, for example, the conveyance mechanism 20 unloads the template 5 from the process chamber 31 of the cleaning module 30, and conveys the unloaded template 5 to the ashing module 40.

The ashing module 40 is arranged adjacent to the conveyance mechanism 20. The ashing module 40 includes a process chamber 41 used for performing an ashing process for removing the auxiliary agent that remains on the template 5 after the cleaning process is performed to the template 5. The template 5 to be processed is loaded into the process chamber 41 by the conveyance mechanism 20.

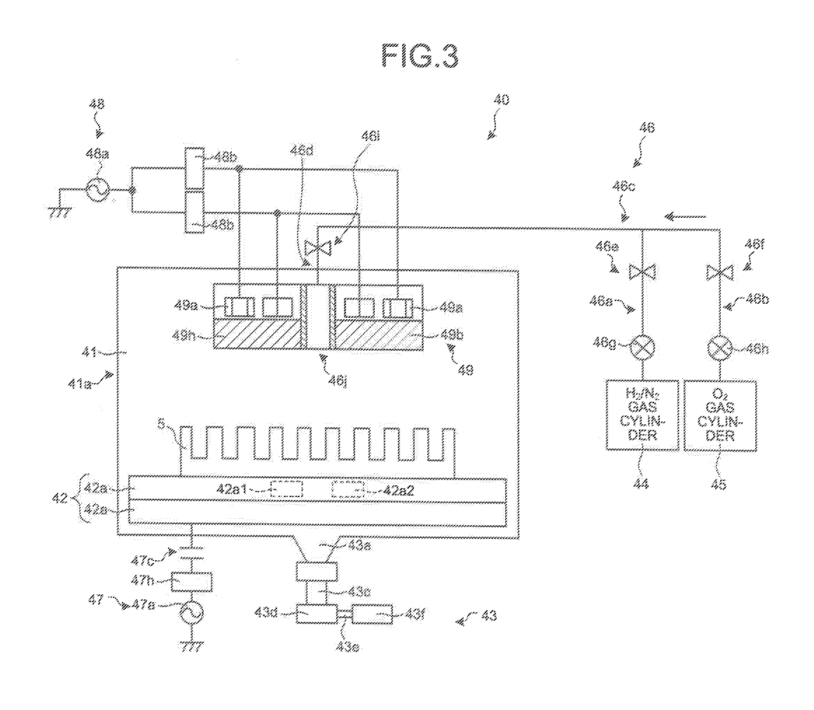

More specifically, the ashing module 40 has a configuration as illustrated in FIG. 3. FIG. 3 is a diagram illustrating the configuration of the ashing module 40. The ashing module 40 includes a process chamber 41, a holding mechanism 42, a gas exhaust system 43, an H₂/N₂ gas cylinder 44, an O₂ gas cylinder 45, a gas supply system 46, a power supply 47, a power supply 48, and a plasma generation module 49.

The process chamber 41 is a chamber for generating plasma inside, and is formed of a process container 41a. The process container 41a is configured to supply a process gas from the gas supply system 46 into the process chamber 41. Further, the process container 41a is configured to exhaust the used process gas from the process chamber 41 into the gas exhaust system 43.

The holding mechanism 42 is arranged inside the process chamber 41, and holds the template 5 loaded in the process chamber 41. The holding mechanism 42 includes a stage 42a and an electrode part 42b. The stage 42a includes a chucking mechanism, such as an electrostatic chuck or vacuum chuck, and holds the placed template 5 by the chucking mechanism. The stage 42a is provided with a temperature sensor 42a1 and a temperature regulator (heater) 42a2. A controller (not shown) performs feedback control to an output from the temperature regulator 42a2 to cause a temperature measured by the temperature sensor 42a1 to be closer to a target temperature. The electrode part 42b is supplied with a power from the power supply 47, and supplies the power to the stage 42a.

The gas supply system 46 includes gas supply pipes 46a, 46b, 46c, and 46d, switching valves 46e, 46f, and 46i, flow regulating valves 46g and 46h, and a delivery port 46j.

The gas exhaust system 43 includes a gas exhaust pipe 43a, a pressure controller 43b, a gas exhaust pipe 43c, a vacuum pump 43d, a gas exhaust pipe 43e, and a vacuum pump 43f.

The power supply 48 is a power supply used for supplying a power for processing the template 5, and supplies a radio frequency power to the plasma generation module 49. The power supply 48 includes a radio frequency power supply 48a and a matching box 48b.

The plasma generation module 49 generates plasma in a space above the stage 42a inside the process chamber 41 by using the power supplied from the power supply 48. Specifically, the plasma generation module 49 includes an antenna coil 49a and a dielectric wall 49b. The radio frequency power supply (RF power supply) 48a generates a radio frequency power, and supplies the power to the antenna coil 49a. Under the control of the controller (not shown), when the impedance matching between the radio frequency power supply 48a and the antenna coil 49a is achieved by the matching box 48b, electromagnetic waves are transmitted through the dielectric wall 49b and introduced into the space inside the process chamber 41. In the space inside the process chamber 41, plasma is generated by ionization of the process gas, and thus radicals and ions are generated from the process gas.

The power supply 47 generates a bias voltage on the electrode part 42b arranged on the bottom side inside the process chamber 41. Specifically, the power supply 47 includes a radio frequency power supply (RF power supply) 47a, a matching box 47b, and a blocking capacitor 47c. The radio frequency power supply 47a generates a radio frequency power. Under the control of the controller (not shown), when the impedance matching is achieved by the matching box 47b, a bias voltage is applied to the electrode part 42b through the blocking capacitor 47c. When the bias voltage is applied, a potential difference is generated with respect to the plasma, and ions generated in the plasma area are attracted toward the template 5 by the bias voltage. Together with the ions being attracted, radicals are led to the template 5 and act thereon, whereby an ashing process is performed to the auxiliary agent (organic substance) remaining on the surface of the template 5.

For example, when the process gas is H₂/N₂ mixed gas, H₂ radicals cut alkyl chains in the organic substance, and alkyl radicals are generated. The alkyl radicals are fragmented by progressive reduction under the action of hydrogen, and end up being evaporated in the form of CO₂ and H₂O (water vapor). On the other hand, when one process gas is O₂ gas, O₂ radicals cut alkyl chains in the organic substance, and alkyl radicals are generated. The alkyl radicals are fragmented by progressive oxidation under the action of oxygen, and end up being evaporated in the form of CO₂ and H₂O (water vapor).

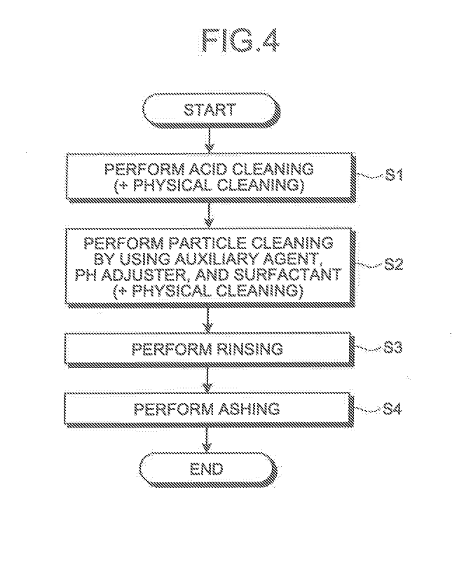

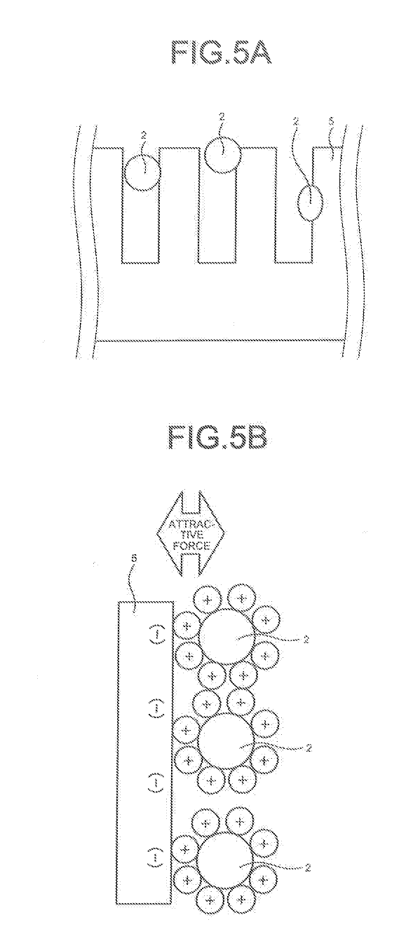

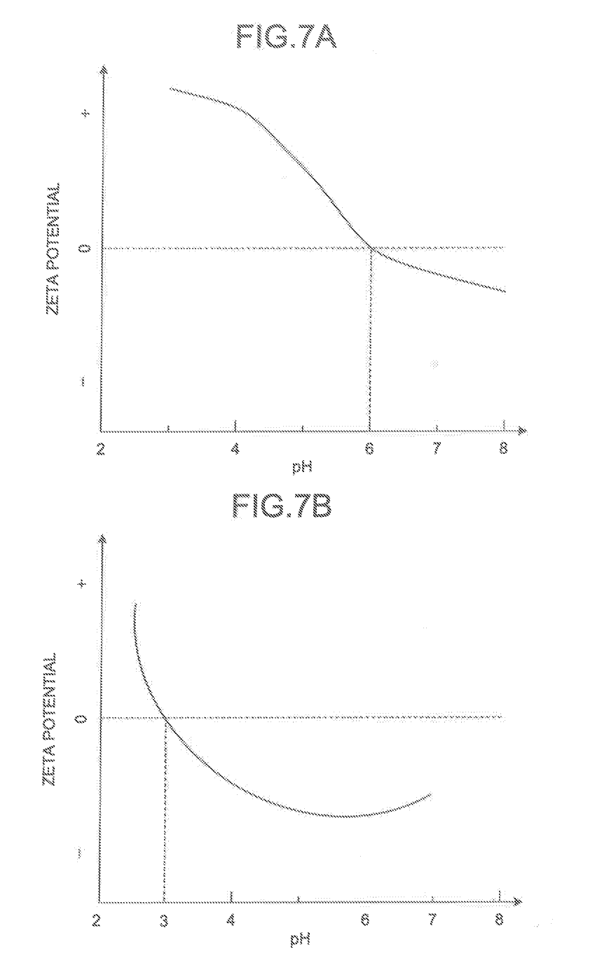

Next, an explanation will be given of a cleaning method of the template 5, with reference to FIGS. 4 to 8C. FIG. 4 is a flowchart illustrating a cleaning method of the template 5. FIGS. 5A, 5B, 6A, 6B, and 8A to FIG. 8C are diagrams illustrating the cleaning method of the template 5. FIGS. 7A and 7B are diagrams illustrating the surface potential (zeta potential) of an auxiliary agent and that of the template.

For example, it is assumed that the cleaning module 30-1 is a cleaning module for acid cleaning and the cleaning module 30-2 is a cleaning module for alkali cleaning. The cleaning module 30-1 performs acid cleaning to the template 5 (S1). Specifically, the template 5 is loaded into the process chamber 31 by the conveyance mechanism 20, and the cleaning module 30-1 holds the template 5 on the stage 32a. Then, while rotating the stage 32a, the cleaning module 30-1 selectively opens the switching valves 38n and 38o to deliver a cleaning agent for acid cleaning from the delivery port 38r onto the surface 5a of the template 5.

For example, the cleaning agent for acid cleaning is SPM (a mixed liquid of sulfuric acid, with hydrogen peroxide solution), HPM (a mixed liquid of hydrochloric acid with hydrogen peroxide solution), COM (a mixed liquid of hydrochloric acid with ozone water), or the like. Consequently, resist and/or metal dust attaching to the template 5 can be removed.

It should be noted that the cleaning module 30-1 may perform physical cleaning in addition to delivery of the cleaning agent for acid cleaning. Specifically, the cleaning module 30-1 opens the switching valve 38p, in place of the Switching valve 38o, to deliver the cleaning agent for acid cleaning from the delivery port 38s onto the surface 5a of the template 5. At this time, cavities (micro-bubbles) are generated in the cleaning agent for acid cleaning, and the cleaning agent for acid cleaning is delivered to the template 5. Consequently, resist and/or metal dust attaching to the template 5 can be efficiently removed.

At this time, as illustrated in FIG. 5A, particles 2 may be present inside the recessed portions on the template 5. Further, when the surface potential of the template 5 is a negative potential and the surface potential of the particles 2 is a positive potential, as illustrated in FIG. 5B, an electrical attractive force works between the particles 2 and the template 5. Consequently, the particles 2 can remain while attaching to the surface of the template 5.

Returning back to FIG. 4, upon completion of the cleaning at S1, the cleaning module 30-1 performs cleaning for removing particles to the template 5, by using an auxiliary agent, a pH adjuster, and a surfactant (S2). Specifically, while holding the template 5 on the stage 32a and rotating the stage 32a, the cleaning module 30-1 selectively opens the switching valves 38k and 38o to deliver a surfactant from the delivery port 38r onto the surface 5a of the template 5.

For example, the surfactant may be an anionic surfactant, cationic surfactant, nonionic surfactant, or combination thereof. The anionic surfactant encompasses dodecylbensene sulfonate salt, polymeric polyacrylate salt, and the like. The cationic surfactant encompasses aliphatic amine salt, aliphatic ammonium salt, and the like. The nonionic surfactant encompasses polyvinyl pyrrolidone (PVP), acetylene glycol, a silicone-based surfactant, polyvinyl alcohol, polyvinylmethyl ether, hydroxyethyl cellulose, and the like.

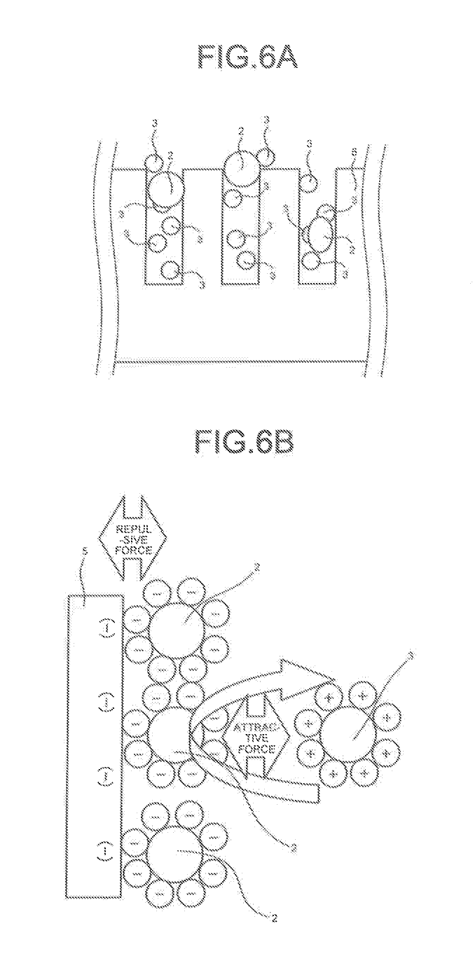

At this time, as illustrated in FIG. 6B, when the surface potential of the template 5 is a negative potential, as the surfactant containing an anionic surfactant as the main component is supplied to the particles 2, the surface potential of the particles 2 can become a negative potential. Consequently, the surface potential of the particles 2 is made the same in polarity as the surface potential of the template 5, and thus an electrical repulsive force can come to work between the particles 2 and the template 5.

However, in this state, if a physical connecting force works between the particles 2 and the template 5, the particles 2 can remain while attaching to the surface of the template 5.

Accordingly, while holding the template 5 on the stage 32a and rotating the stage 32a, the cleaning module 30-1 selectively opens the switching valves 38i, 38j, and 38o to deliver an auxiliary agent and a pH adjuster from the delivery port 38r onto the surface 5a of the template 5.

The auxiliary agent contains grains of an organic substance. For example, the organic substance may be made of a resin (resin) containing no metal. The organic substance contains a material that contains as the main component at least one selected from the group consisting of a styrene-based resin, acrylic-based, resin, acrylic styrene-based resin, and melanin-based resin. For example, the organic substance contains polystyrene. The average primary grain diameter of the grains contained in the auxiliary agent may be set to correspond to the minimum dimension of the pattern formed on the template surface (for example, several 10 nm to 60 nm), and may be set to 5 nm or larger and 60 nm or smaller, for example.

The pH adjuster is a chemical liquid for adjusting the surface potential (zeta potential) of the auxiliary agent, to cause the particles to attach to the auxiliary agent. The pH adjuster adjusts the surface potential (zeta potential) of the auxiliary agent to a polarity reverse to that of the surface potential of the particles. For example, the pH adjuster contains potassium hydroxide and/or sulfuric acid.

For example, when the auxiliary agent contains grains made of a material that contains polystyrene as the main component, the pH and the surface potential of the grains of the auxiliary agent have a relationship therebetween as illustrated in FIG. 7A. The equipotential point of the grains of the auxiliary agent is at about 6, which suggests that the surface potential of the grains of the auxiliary agent can be adjusted to a positive potential by setting the pH of the chemical liquid to about 6 or less. On the other hand, when the template 5 is made of a material that contains silicon oxide (quartz) as the main component, the pH and the surface potential of the template 5 have a relationship therebetween as illustrated in FIG. 7B. The equipotential point of the template 5 is at about 3, which suggests that, the surface potential of the template 5 can be adjusted to a negative potential by setting the pH of the chemical liquid to about 3 or more.

Accordingly, on the basis of FIGS. 7A and 7B, it is understandable that the surface potential of the auxiliary agent and the surface potential of the template 5 can be adjusted to polarities reverse to each other by adjusting the pH of the chemical liquid to about 3 or more and about 6 or less. Accordingly, the pH adjuster may be a chemical liquid in which the mixture ratio between potassium hydroxide and sulfuric acid is adjusted in advance to adjust the pH of the chemical liquid to about 3 or more and about 6 or less.

At this time, as illustrated in FIG. 6A, the auxiliary agent 3 may be present, in addition to the particles 2, inside the recessed portions on the template 5. Further, from a state where the surface potential of the template 5 is a negative potential and the surface potential of the particles 2 is a negative potential, when the surface potential of the auxiliary agent 3 becomes a positive potential by the action of the pH adjuster, as illustrated in FIG. 6B, an electrical attractive force works between the particles 2 and the auxiliary agent 3. Consequently, the particles 2 can be made to attach to the auxiliary agent 3, and the auxiliary agent 3 with the particles 2 attaching thereto can be easily discharged to the waste liquid piping 33 by effects of rotation of the spin module 32 (such as a centrifugal force, chemical liquid flow, and so forth).

It should be noted that the cleaning module 30-1 may perform physical cleaning that applies vibration to the auxiliary agent, in addition to delivery of the auxiliary agent and the pH adjuster. Specifically, the cleaning module 30-1 opens the switching valve 38p, in place of the switching valve 38o, to deliver the auxiliary agent and the pH adjuster from the delivery port 30s onto the surface 5a of the template 5. At this time, cavities (micro-bubbles) are generated in the auxiliary agent and the pH adjuster, and the auxiliary agent and the pH adjuster are delivered to the template 5. Consequently, the grains of the auxiliary agent 3 are supplied with vibration, which increases the probability that the grains of the auxiliary agent 3 can come closer to the particles 2 and allow the particles 2 to attach to the grains of the auxiliary agent 3. As a result, it is possible to improve the removal rate of the particles 2 obtained by discharging the grains of the auxiliary agent 3 with the particles 2 attaching thereto.

Returning back to FIG. 4, upon completion of the cleaning at S2, the cleaning module 30-1 rinses the template 5 (S3). Specifically, while holding the template 5 on the stage 32a and rotating the stage 32a, the cleaning module 30-1 selectively opens the switching valves 38y and 38o to deliver a rinse liquid from the delivery port 38r onto the surface 5a of the template 5.

The rinse liquid is a liquid for rinsing the template 5. For example, the rinse liquid is pure water or ultrapure water.

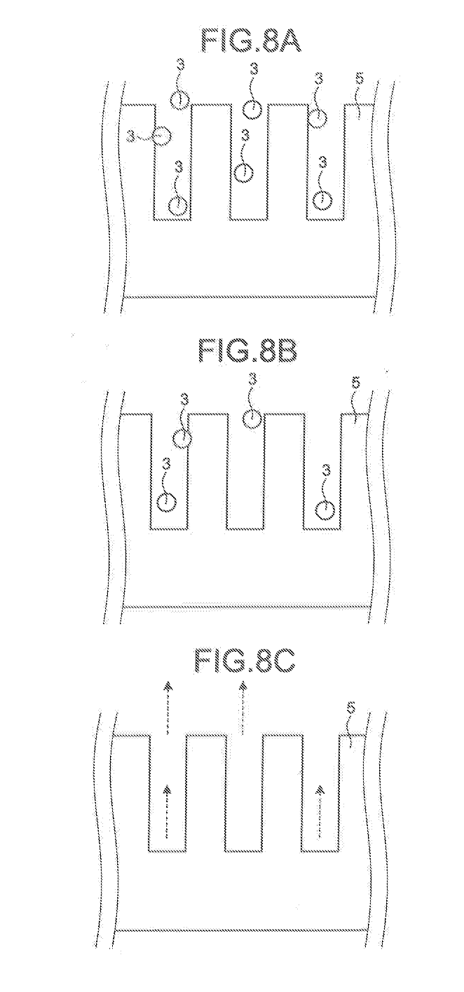

At this time, as illustrated in FIG. 8A, in a state where the cleaning at S2 has been completed, the auxiliary agent 3 may be present inside the recessed portions on the template 5. Because the surface potential of the template 5 is a negative potential and the surface potential of the auxiliary agent 3 is a positive potential, when the template 5 is rinsed by the rinse liquid, as illustrated in FIG. 8B, the auxiliary agent 3 can remain while attaching to the surface of the template 5.

Returning back to FIG. 4, the ashing module 40 performs an ashing process to the surface of the template 5 (S4). Specifically, the template 5 is loaded into the process chamber 41 by the conveyance mechanism 20, and the ashing module 40 holds the template 5 on the stage 42a. Then, the ashing module 40 supplies a process gas into the process chamber 41, and generates plasma in the space inside the process chamber 41, to cause radicals of the process gas to act on the surface of the template 5. For example, the ashing module 40 selectively opens the switching valves 46e and 46i to supply H₂/N₂ mixed gas from the delivery port 46j into the process chamber 41, and, meanwhile, generates plasma in the space inside the process chamber 41, to cause H₂ radicals to act on the surface of the template 5. Alternatively, for example, the ashing module 40 selectively opens the switching valves 46f and 46i to supply O₂ gas from the delivery port 46j into the process chamber 41, and, meanwhile, generates plasma in the space inside the process chamber 41, to cause O₂ radicals to act on the surface of the template 5.

At this time, because the auxiliary agent 3 remaining by attaching to the surface of the template 5 as illustrated in FIG. 8B contains grains made mainly of an organic substance, the auxiliary agent 3 is decomposed by the H₂ radicals or O₂ radicals, and is evaporated in the form of CO₂ and H₂O (wafer vapor), as illustrated by broken arrows in FIG. 8C. In other words, the auxiliary agent 3 remaining by attaching to the surface of the template 5 can be easily removed from the template 5 by the ashing process.

As described above, according to this embodiment, cleaning is performed to the template 5 by using the auxiliary agent and the pH adjuster. Specifically, the surface potential of the fine grains of the auxiliary agent is set to have a polarity reverse to that of the surface potential of particles. In this state, the particles are caused to attach to the fine grains of the auxiliary agent, and then the fine grains of the auxiliary agent with the particles attaching thereto are removed. Consequently, it is possible to remove particles by raking them out with the auxiliary agent, without applying an additional force to the template 5, and thereby to improve the particle remove efficiency while protecting the pattern on the template 5.

Further, in the embodiment, after cleaning is performed to the template 5 by using the auxiliary agent and the pH adjuster, the ashing process is performed to the surface of the template 5. Consequently, it is possible to easily remove the auxiliary agent 3 remaining by attaching to the surface of the template 5, from the template 5.

Further, in the embodiment, in addition to the cleaning using the auxiliary agent and the pH adjuster, physical cleaning that applies vibration to the auxiliary agent may be performed. Consequently, it is possible to increase the probability that the grains of the auxiliary agent can come closer to the particles and allow the particles to attach to the grains of the auxiliary agent. As a result, it is possible to improve the removal rate of the particles obtained by discharging the grains of the auxiliary agent with the particles attaching thereto.

It should be noted that, in the embodiment, as the physical cleaning that applies vibration to the auxiliary agent, in place of the cleaning that supplies ultrasonic waves to a chemical liquid to generate cavities, or in addition to this cleaning, another type of clearing may be performed. For example, the chemical liquid temperature adjusting mechanism 39 may be used to heat water contained in the auxiliary agent to activate the lattice vibration of water molecules, and thereby to apply vibration to the auxiliary agent. Alternatively, it may be adopted to heat water contained in the auxiliary agent by irradiation with microwaves to activate the lattice vibration of water molecules, and thereby to apply vibration to the auxiliary agent.

Alternatively, in the cleaning method of the template 5 illustrated in FIG. 4, alkali cleaning corresponding to that of S1 (+physical cleaning), particle cleaning similar to that of S2 (+physical cleaning), and rinsing similar to that of S3 may be further performed between S3 and S4. Further, in place of S1 to S3, alkali cleaning corresponding to that of S1 (+physical cleaning), particle cleaning similar to that of S2 (+physical cleaning), and rinsing similar to that of S3 may be performed. Further, after S4, alkali cleaning corresponding to that of S1 (+physical cleaning) and rinsing similar to that of S3 may be further performed.

Alternatively, as regards the auxiliary agent and the pH adjuster, instead of being separately stored in tanks (the auxiliary agent tank 34 and the pH adjuster tank 35 illustrated in FIG. 2), they may be prepared as one cleaning liquid and stored in one tank. Alternatively, as regards the auxiliary agent, the pH adjuster, and the surfactant, instead of being separately stored in tanks (the auxiliary agent tank 34, the pH adjuster tank 35, and the surfactant tank 36 illustrated in FIG. 2), they may be prepared as one cleaning liquid and stored in one tank.

For example, in one cleaning liquid, its pH has been adjusted to 3 or more and 6 or less by the pH adjuster. In one cleaning liquid, the auxiliary agent contains grains made of a material that contains an organic substance as the main component. The average primary grain diameter of the grains of the auxiliary agent may be set to correspond to the minimum dimension of the pattern formed on the template surface (for example, several 10 nm to 60 nm), and may be set to 5 nm or larger and 60 nm or smaller, for example.

The density of the grains of the auxiliary agent contained in one cleaning liquid is a density that enables the auxiliary agent to remove the particles by raking them out, and is set to 0.5 wt % or higher and 20 wt % or lower, for example. If the density of the grains of the auxiliary agent contained in one cleaning liquid is lower than 0.5 wt %, the grains of the auxiliary agent become difficult to come closer to the particles, and the probability that the particles attach to the grains of the auxiliary agent tends to be lower than the required level. If the density of the grains of the auxiliary agent contained in one cleaning liquid is higher than 20 wt %, discharge of the grains of the auxiliary agent with the particles attaching thereto is likely to be inhibited by the other grains of the auxiliary agent, and tends to make it difficult to efficiently remove the particles.

Alternatively, the auxiliary agent may contain grains made of a material that contains serum albumen as the main component. In this case, the equipotential point of the grains of the auxiliary agent can be at about 5.23, and thus the surface potential of the grains of the auxiliary agent can be adjusted to a positive potential by setting the pH of the chemical liquid to about 5.23 or less (see FIG. 7A). In this case, the pH adjuster may be a chemical liquid in which the mixture ratio between potassium hydroxide and sulfuric acid is adjusted in advance to adjust the pH of the chemical liquid to about 3 or more and about 5.23 or less.

Alternatively, the auxiliary agent may contain grains made of a material that contains PMMA (polymethyl metacrylate) and serum albumin as the main component. In this case, the equipotential point of the grains of the auxiliary agent can be at about 4.88, and thus the surface potential of the grains of the auxiliary agent can be adjusted to a positive potential by setting the pH of the chemical liquid to about 4.88 or less (see FIG. 7A). In this case, the pH adjuster may be a chemical liquid in which the mixture ratio between potassium hydroxide and sulfuric acid is adjusted in advance to adjust the pH of the chemical liquid to about 3 or more and about 4.88 or less.

Alternatively, the auxiliary agent may contain grains made of a material that contains PMMA (polymethyl metacrylate) as the main component. In this case, the equipotential point of the grains of the auxiliary agent can be at about 3.37, and thus the surface potential of the grains of the auxiliary agent can be adjusted to a positive potential by setting the pH of the chemical liquid to about 3.37 or less (see FIG. 7A). In this case, the pH adjuster may be a chemical liquid in which the mixture ratio between potassium hydroxide and sulfuric acid is adjusted in advance to adjust the pH of the chemical liquid to about 3 or more and about 3.37 or less.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A template cleaning method comprising:
cleaning a template with a pattern formed on a surface, by using an acid or alkali;
cleaning the template by using a cleaning liquid;
rinsing the template by using a rinse liquid; and
performing an ashing process to the surface of the template by using a process gas,
wherein
the cleaning liquid contains at least an auxiliary agent and a pH adjuster, and
the auxiliary agent contains grains made of a material that contains an organic substance as a main component.

2. The template cleaning method according to claim 1, wherein
the grains have an average primary grain diameter that corresponds to a minimum dimension of the pattern formed on the surface of the template.

3. The template cleaning method according to claim 1, wherein
the average primary grain diameter of the grains is 5 nm or larger and 60 nm or smaller.

4. The template cleaning method according to claim 1, wherein
the organic substance contains a material that contains as a main component at least one selected from a group consisting of a styrene-based resin, acrylic-based resin, acrylic styrene-based resin, and melanin-based resin.

5. The template cleaning method according to claim 4, wherein
the organic substance contains polystyrene.

6. The template cleaning method according to claim 5, wherein
the pH adjuster adjusts a pH of the cleaning liquid to 3 or more and 6 or less.

7. The template cleaning method according to claim 4, wherein
the organic substance contains PMMA (polymethyl metacrylate).

8. The template cleaning method according to claim 7, wherein
the pH adjuster adjusts a pH of the cleaning liquid to 3 or more and 3.37 or less.

9. The template cleaning method according to claim 1, wherein
the cleaning liquid further contains a surfactant.

10. The template cleaning method according to claim 9, wherein
the surfactant is to adjust a surface potential of particles attaching to the template to a first potential and
the pH adjuster is to adjust a surface potential of the auxiliary agent to a second potential having a polarity reverse to that of the first potential.

11. The template cleaning method according to claim 10, wherein
the pH adjuster is to adjust a surface potential of the template to a third potential having a polarity reverse to that of the first potential, and to adjust a surface potential of the auxiliary agent to the second potential.

12. The template cleaning method according to claim 1, wherein
the cleaning includes cleaning the template by using the cleaning liquid while rotating the template.

13. The template cleaning method according to claim 1, wherein
the cleaning includes cleaning the template by using the cleaning liquid while applying vibration to the auxiliary agent.

14. The template cleaning method according to claim 1, wherein
the cleaning includes cleaning the template by using the cleaning liquid while rotating the template and while applying vibration to the auxiliary agent.

15. A template cleaning apparatus comprising:
a first process chamber;
a first supply part configured to supply an auxiliary agent to the first process chamber;
a second supply part configured to supply a pH adjuster to the first process chamber;
a second process chamber;
an irradiation part configured to perform irradiation with plasma in the second process chamber,
wherein the auxiliary agent contains grains made of a material that contains an organic substance as a main component.

16. The template cleaning apparatus according to claim 15, further comprising a third supply part configured to supply a surfactant to the first process chamber.

17. The template cleaning apparatus according to claim 15, further comprising:
a first stage arranged in the first process chamber and configured to rotatably hold the template; and
a second stage arranged in the second process chamber.

18. The template cleaning apparatus according to claim 15, further comprising a vibration imparting mechanism configured to apply vibration to the auxiliary agent.

19. A cleaning liquid comprising an auxiliary agent containing grains made of a material that contains an organic substance as a main component, the cleaning liquid being a liquid to be used for cleaning a template.

20. The cleaning liquid according to claim 19, further comprising a pH adjuster that adjusts a surface potential of the auxiliary agent.
